(19) United States
(12) Patent Application Publication
(10) Pub. No.: US 2006/0152139 A1
(43) Pub. Date: Jul. 13, 2006

(54) Wavelength converting substance and light emitting device and encapsulating material comprising the same

(76) Inventors: Hsiang-Cheng Hsieh, Tao-Yuan Hsien (TW); Chih-Chin Chang, Hsin-Chu City (TW); Teng-Huei Huang, Hsin-Chu Hsien (TW); Tse-Min Mao, Taipei City (TW)

Correspondence Address: NORTH AMERICA INTELLECTUAL PROPERTY CORPORATION, P.O. BOX 506, MERRIFIELD, VA, 22116, US

(21) Appl. No.: 10/908,189

(22) Filed: May 2, 2005

(30) Foreign Application Priority Data
Jan. 12, 2005 (TW) 094100845

(51) Int. Cl. H01J 1/62; H01L 33/00

(52) U.S. Cl. 313/503; 313/512

(57) ABSTRACT

A wavelength converting substance comprises a wavelength converting material particle and a transparent layer on the wavelength converting material particle. The wavelength converting substance is a material possessing both wavelength converting and light scattering properties. Thus, when the wavelength converting substance is used in a light emitting device, the brightness is improved and the light mixing is more uniform than that of a traditional package. A light emitting device and an encapsulating material comprising the wavelength converting substance are also disclosed.

### BACKGROUND OF INVENTION

1. Field of the Invention

The present invention relates a wavelength converting substance, a light device comprising the wavelength converting substance, and an encapsulating material for a LED device comprising the wavelength converting substance.

2. Description of the Prior Art

Recently, the new application fields of high illumination light emitting diodes (LEDs) have been developed. Different from a common incandescent light, a cold illumination LED has the advantages of low power consumption, long device lifetime, no idling time, and quick response speed. In addition, since the LED also has the advantages of small size, being suitable for mass production, and being easily fabricated as a tiny device or an array device, it has been widely applied in display apparatuses and indicating lamps of information, communication, and consumer electronic products. The LEDs are not only utilized in outdoor traffic signal lamps or various outdoor displays, but also are very important components in the automotive industry. Furthermore, the LEDs also work well in portable products, such as cell phones and backlights of personal data assistants. The LED has become a necessary key component in the very popular liquid crystal display because it is the best choice when selecting the light source of the backlight module.

A common light emitting diode package comprises a light emitting diode device. When light is emitted from the light emitting diode device, a series of procedures including diffusing, reflecting, mixing, or light wavelength conversion proceed in a molding material or encapsulating material to generate satisfactory chromatology and brightness. Therefore, the selection of the molding material or encapsulating material is important to design a light emitting diode package.

Encapsulating material comprising wavelength converting material and diffuser is used in most conventional LED devices. Wavelength converting material is also known as a material emitting light passively. For example, a series of fluorescent powder are used to convert blue light or UV light into a light having another wavelength, usually a yellow, red, blue, or green light. Part of the blue light transmits through the fluorescent powder and mixes with the yellow light to form a white light. Some LED devices use red, blue, or green light as an active light source. Some LED devices use red, blue, or green light converting material to hybridize a white light. FIG. 1 is a schematic diagram showing a conventional fluorescent material particle. The fluorescent material particle 10 receives incident light having a wavelength λ₁ and converts it into a light having a wavelength λ₂. Encapsulating material usually further comprises photo-inert and high reflective material particles or air bubbles for more uniform light mixing, that is also known as diffusers, such as, SiO₂, PMMA, Si₃N₄, GaN, InGaN, AlInGaN, and air bubbles. However, these diffusers will consume light intensity, and thus the brightness of the LED device is lowered.

FIG. 2 shows a schematic diagram of a conventional lead type light emitting diode package 20. The conventional lead type light emitting diode package 20 comprises a light emitting diode chip 21, a mount lead 24, and an inner lead 25. The mount lead 24 further comprises a cup 26. The mount lead 24 is used as a negative electrode, and the inner lead 25 is used as a positive electrode. The light emitting diode chip 21 is disposed in the cup 26 of the mount lead 24. A P electrode and an N electrode (both are not shown in the figure) of the light emitting diode chip 21 are connected to the mount lead 24 and the inner lead 25, respectively, by conductive wires 23. The cup 26 is filled with a molding material 22. A plurality of fluorescent materials (not shown) are dispersed in the molding material 22. Epoxy resin 27 encapsulates the entire light emitting diode, conductive wires, cup, and leads, but to expose one end of each lead.

FIG. 3 is a schematic diagram of a conventional chip type light emitting diode package 30. The light emitting diode package 30 comprises a light emitting diode chip 31 and a casing 32. The casing 32 further comprises a positive metal terminal 34 and a negative metal terminal 35. The positive metal terminal 34 is used as a positive electrode, and the negative metal terminal 35 is used as a negative electrode. The light emitting diode chip 31 is disposed in a recess 36 of the casing 32 and is on top of the positive metal terminal 34. A P electrode and an N electrode (both are not shown in the figure) of the light emitting diode chip 31 are connected to the positive metal terminal 34 and the negative metal terminal 35, respectively, by conductive wires 43. The recess 36 is filled with a molding material 37. A plurality of fluorescent materials (not shown) are spread in the molding material 37.

The lead type LED package 20 and the chip type LED package 30 mentioned above have different package structure and both can attained the white light or other colored light by light mixing. Different package structures result different light emitting. However, light intensity loss is encountered by the conventional package structure due to the interface properties between the fluorescent material and the matrix material or the properties of diffusing particle or layers used, such that the device brightness is lowered.

Therefore, improvement for brightness of LED packages and improved properties for encapsulating material are still needed.

### SUMMARY OF INVENTION

Accordingly, an objective of the present invention is to provide a wavelength converting substance having a structure different from a typical fluorescent material. The wavelength converting substance is a material possessing both wavelength converting and light scattering properties, and, when used in a light device or as an encapsulating material, it can improve brightness and light mixing uniformity for the light device. The wavelength converting substance also has an improved heat resistance.

The wavelength converting substance of the present invention comprises a wavelength converting material particle and a transparent layer on the surface of the wavelength converting material particle.

In another aspect of the present invention, a light device is provided. The light device comprises a light emitting element for emitting a first light when driven, a plurality of wavelength converting substances located to receive the first light and converting the first light to a second light, wherein each wavelength converting substance comprises a wavelength converting material particle and a transparent layer covering the wavelength converting material particle continuously or in an island-like way.

In still another aspect of the present invention, an encapsulating material for a light emitting diode is provided. The encapsulating material comprises a matrix and at least one wavelength converting substance as claimed in claim 1 dispersed in the matrix.

In further another aspect of the present invention, a light device is provided. The device comprises an electron beam emitting element emitting an electron beam when driven, a plurality of wavelength converting substances located to receive the electron beam emitted by the electron beam emitting element and converting the electron beam to a light, wherein each wavelength converting substance comprises a wavelength converting material particle and a transparent layer covering the wavelength converting material particle continuously or in an island-like.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram showing a conventional fluorescent material particle.

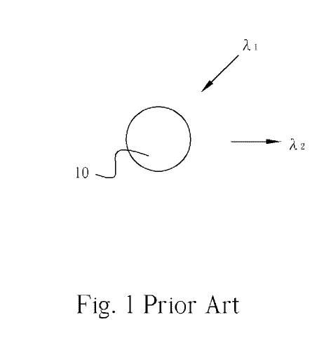

FIG. 2 is a schematic diagram of a conventional lead type light emitting diode package.

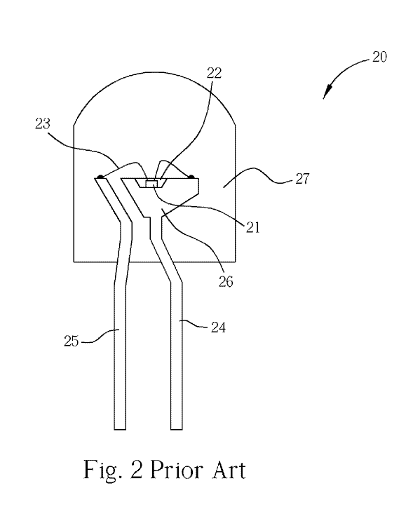

FIG. 3 is a schematic diagram of a conventional chip type light emitting diode package.

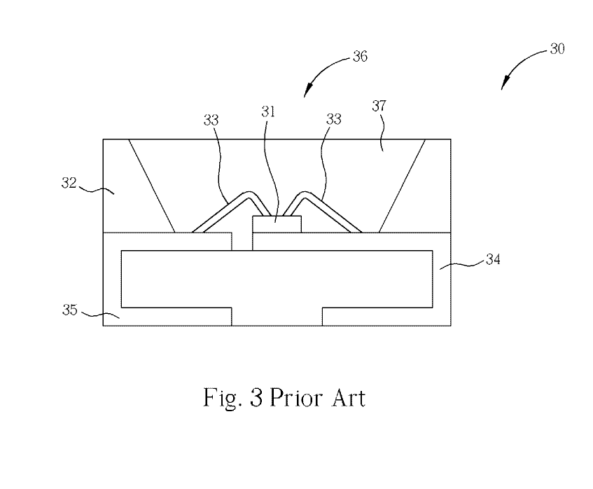

FIG. 4 is a schematic diagram showing a wavelength converting substance according to the present invention.

FIG. 5 is a schematic diagram showing another wavelength converting substance according to the present invention.

FIG. 6 is a schematic diagram showing the relation between each two phases in phases 1, 2, and 3.

FIG. 7 is a plotting showing the heat resistance of a conventional YAG and the wavelength converting substance according to the present invention in LED packages, respectively.

FIG. 8 is a plotting showing the luminance difference between LED packages using the wavelength converting substance according to the present invention and a conventional YAG, respectively.

### DETAILED DESCRIPTION

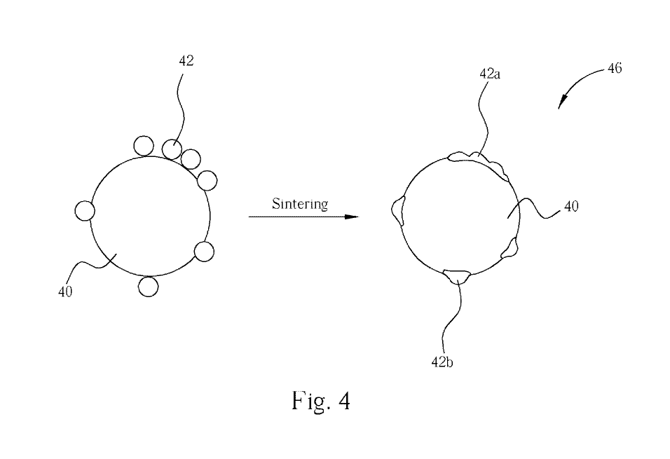

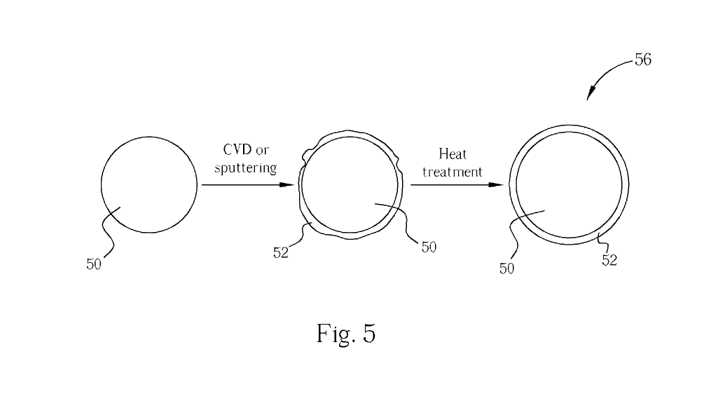

Please refer to FIGS. 4 and 5. FIGS. 4 and 5 are schematic diagrams showing the structure of the wavelength converting substance 46 and 56 according to the present invention and the manufacture thereof. The wavelength converting substance 46 comprises a wavelength converting material particle 40 and a transparent layer 42a and/or 42b. The wavelength converting substance 56 comprises a wavelength converting material particle 50 and a transparent layer 52. The transparent layer is formed on the surface of the wavelength converting material particle.

The wavelength converting material particle used in the present invention is a particle made of material which emits light passively, for example, fluorescent material, phosphorescent material, dye material, or a combination thereof; that is, the material has a function to convert a light with a wavelength into another light with a different wavelength. The wavelength converting material may be exemplified by a material represented by a general formula (A)₃₊ₜ₊ᵤ(B′)₅₊ᵤ₊₂ᵥ(C)₁₂₊₂ₜ₊₃ᵤ₊₃ᵥ:D, wherein 0<t<5, 0<u<15, 0<v<9, A is at least one selected from Y, Ce, Tb, Gd, and Sc, B′ is at least one selected from Al, Ga, TI, In, and B, C is at least one selected from O, S, and Se, and D is at least one selected from Ce and Tb.

Next, particulate-like transparent material having a size of micrometers to nanometers is attached to the surface of the wavelength converting material particle and sintered, forming a transparent layer covering portions of the surface of the wavelength converting material particle. For example, as shown in FIG. 4, the transparent layer 42a continuously covers a portion of the surface of the wavelength converting material particle 40, and the transparent layer 42b is distributed in an island-like way to cover portions of the surface of the wavelength converting material particle 40. Alternatively, as shown in FIG. 5, a transparent layer 52 may be obtained on the entire surface of the wavelength converting material particle 50 by performing a chemical vapor deposition, physical vapor deposition, or sputtering on the surface of the wavelength converting material particle 50. A heat treatment may be further performed to enhance the uniformity and planarity of the surface of the transparent layer 52.

One function of the transparent layer 42a, 42b, or 52 is to scatter the light from the wavelength converting material particle 40 or 50, and another function is to passivate the surface of the wavelength converting material particle 40 or 50 to improve the heat resistance. Therefore, the wavelength converting substance according to the present invention has relatively high heat resistance.

The thickness of the transparent layer is preferably about 50 Å to 2 μm. The size of the wavelength converting material particle may be, but not limited to, 5000 Å to 30 μm. It is preferred that the amount of the transparent layer is 0.1% to 10% in weight based on the weight of the wavelength converting material particle. In this situation, the wavelength converting material particle has a size of from 5 to 30 μm and can be mixed and sintered with transparent material micron particles (such as ITO), or has a size of from 5000 Å to 1 μm and can be mixed and sintered with transparent material nano-particles (such as ITO), but the size of the wavelength converting material particle is not specific limited. The material for the transparent layer may be exemplarily indium tin oxide (ITO) or indium zinc oxide (IZO).

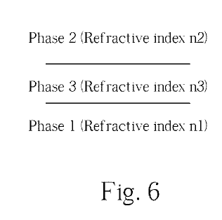

The transparent layer used in the present invention has light scattering properties, and the brightness of the wavelength converting substance can be improved through the control of Fresnel energy loss by selecting material having an appropriate refractive index. The transparent layer used in the present invention preferably has a refractive index not much different from that of the wavelength converting material particle. Please refer to FIG. 6. FIG. 6 is a schematic diagram showing the relation between each two phases in phases 1, 2, and 3. When a light having a wavelength λ goes through two adjacent phases, for example, from phase 1 into phase 2, it is refracted. It is supposed that phase 1 and phase 2 have refractive index n1, n2, respectively. Fresnel reflectance, R1, can be calculated by the following equation: R1=[(n2−n1)/(n2+n1)]². Transmission coefficient=4/(2+n1/n2+n2/n1). When there is a phase 3 (for example, a transparent layer) between phase 1 (for example, wavelength converting material particle) and phase 2 (for example, the ambient environment of the wavelength converting material particle), the Fresnel (reflective) energy loss due to the interface decreases because the transmission coefficient increases, such that the brightness is improved. Preferably, the wavelength converting material particle has a refractive index more than the refractive index of the transparent layer, in a situation of air environment.

Accordingly, the wavelength converting substance according to the present invention comprises a transparent layer on the surface of the wavelength converting material particle and possesses wavelength converting function and scattering function for convenient utilization. The incoming light for the wavelength converting substance to convert is not limited to UV or visible light, and an electron beam is also useful as long as the wavelength converting material is suitably selected. The wavelength converting substance according to the present invention can be used to design a light device. Accordingly, the light device according to the present invention comprises a light emitting element and a plurality of wavelength converting substances. The light emitting element, as a conventional one, emits a light when driven. The plurality of wavelength converting substances are located to receive the light and converting the light to another light having a different wavelength. The light emitting element may be a light emitting diode or other light emitting element. According to the present invention, when an electron beam is used in a light device, the light device comprises an electron beam emitting element and a plurality of wavelength converting substances. The electron beam emitting element emits an electron beam when driven. The plurality of wavelength converting substances are located to receive the electron beam emitted from the electron beam emitting element and converting the electron beam to a light having a wavelength.

The wavelength converting substance according to the present invention can be used as an encapsulating material to encapsulate a light emitting diode. Alternatively, the light device according to the present invention comprising the wavelength converting substance according to the present invention and a light emitting diode can be encapsulated with encapsulating material. In another aspect of the present invention, the wavelength converting substance according to the present invention can be mixed with a matrix, such that the wavelength converting substance is dispersed in the matrix, forming an encapsulating material for use in various light devices, such as conventional lead type LED devices, conventional chip type LED devices, to replace conventional wavelength converting material and scatters. The matrix may be a plastic material (such as epoxy resin), an organic molding compound, a ceramic material permeable to light, a glass material permeable to light, an insulation fluid material permeable to light, or a composite material comprising at least two materials selected from a group consisting of the above-mentioned materials.

### EMBODIMENT

Manufacture of the Wavelength Converting Substance of the Present Invention

About 10 to 15 g of (Tb,Y)₃Al₅O₁₂:Ce⁺³ and ITO nano-particles (in a weight ratio of 10:1) was added to 200 ml of polyvinyl alcohol (PVA) in a drum mixer with zirconium oxide balls as a mixing media and mixed uniformly for about 2 hours. Thereafter, the mixture was sintered at 600° C. for 2 hours, and PVA was vaporized, giving a wavelength converting substance of the present invention.

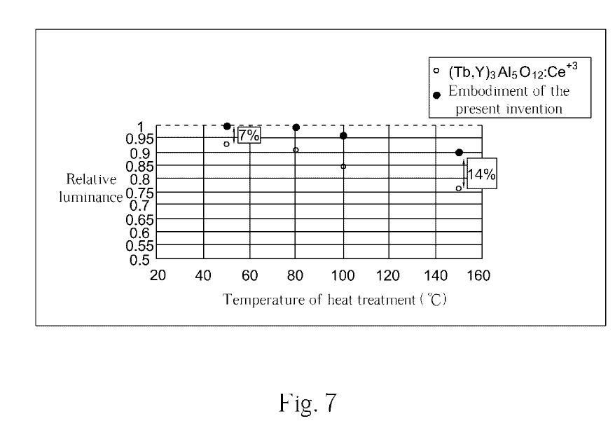

(Tb,Y)₃Al₅O₁₂:Ce⁺³ (a conventional YAG) as a comparative example and the wavelength converting substance of the present invention obtained in the Embodiment were mixed with a silicone glue, a sealing material, respectively, as an encapsulating material to form LED packages. After dried, the mixtures were subjected to a heat treatment at about 50, 80, 100, and 150° C. for 24 hours, respectively. After each heat treatment, the relative luminance of the LED packages using the wavelength converting substance according to the present invention and the comparative example was determined, respectively, using 455 nm blue LED as a light source and 20 mA driving electric current, based on the luminance of the LED package encapsulated with the wavelength converting substance as soon as formed, not heat-treated, in the Embodiment. The results are shown in FIG. 7. Before the heat treatment, the luminance difference is 5%, and after the heat treatment at 50° C., the luminance difference is 7%, between the samples according to the present invention and the comparative example. The luminance difference increased when the temperature for the heat treatment increased. After the heat treatment at 150° C., the luminance difference is 14%. In view of the results, the wavelength converting substance according to the present invention has an improved heat resistance.

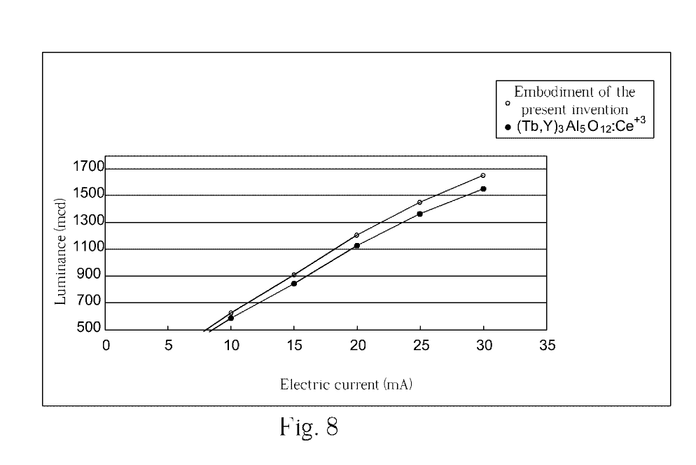

Furthermore, the brightness of LED packages using the wavelength converting substance according to the present invention and the comparative example, respectively, was compared. The luminance (mcd) was determined for the LED package, using a light having a wavelength of 455 to 460 nm, with a size of 13 mil×13 mil, and driven by various electric currents of 10, 15, 20, 25, and 30 mA. The results are shown in FIG. 8. It clearly shows that LED package using the wavelength converting substance according to the present invention has an improved brightness.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wavelength converting substance, comprising:
a wavelength converting material particle; and
a transparent layer on the surface of the wavelength converting material particle.

2. The wavelength converting substance of claim 1, wherein the wavelength converting material particle comprises fluorescent material, phosphorescent material, dye material, or a combination thereof.

3. The wavelength converting substance of claim 1, wherein the transparent layer partially covers the wavelength converting material particle.

4. The wavelength converting substance of claim 3, wherein the transparent layer covering the wavelength converting material particle continuously or in an island-like way.

5. The wavelength converting substance of claim 1, wherein the transparent layer totally covers the wavelength converting material particle.

6. The wavelength converting substance of claim 1, wherein the transparent layer comprises indium tin oxide (ITO) or indium zinc oxide (IZO).

7. The wavelength converting substance of claim 1, wherein the wavelength converting material particle has a refractive index more than the refractive index of the transparent layer.

8. The wavelength converting substance of claim 1, wherein the transparent layer has a thickness of 50 Å to 2 μm.

9. The wavelength converting substance of claim 1, wherein the wavelength converting material particle has a diameter of 5000 Å to 30 μm.

10. The wavelength converting substance of claim 1, wherein the wavelength converting material particle comprises a material represented by a general formula (A)₃₊ₜ₊ᵤ(B′)₅₊ᵤ₊₂ᵥ(C)₁₂₊₂ₜ₊₃ᵤ₊₃ᵥ:D, wherein 0<t<5, 0<u<15, 0<v<9, A is at least one selected from Y, Ce, Tb, Gd, and Sc, B′ is at least one selected from Al, Ga, TI, In, and B, C is at least one selected from O, S, and Se, and D is at least one selected from Ce and Tb.

11. The wavelength converting substance of claim 1, wherein the wavelength converting material particle is a material having a function of wavelength conversion and the transparent layer is a layer having a function of scattering.

12. A light device, comprising:
a light emitting element, emitting a first light when driven;
a plurality of wavelength converting substances located to receive the first light and converting the first light to a second light and each wavelength converting substance comprises a wavelength converting material particle and a transparent layer covering the wavelength converting material particle continuously or in an island-like way.

13. The light device of claim 12, wherein the wavelength converting material particle comprises fluorescent material, phosphorescent material, dye material, or a combination thereof.

14. The light device of claim 12, wherein the transparent layer comprises indium tin oxide (ITO) or indium zinc oxide (IZO).

15. The light device of claim 12, wherein the wavelength converting material particle has a refractive index more than the refractive index of the transparent layer.

16. The light device of claim 12, wherein the transparent layer has a thickness of 50 Å to 2 μm.

17. The light device of claim 12, wherein the wavelength converting material particle has a diameter of 5000 Å to 30 μm.

18. The light device of claim 12, wherein the wavelength converting material particle comprises a material represented by a general formula (A)₃₊ₜ₊ᵤ(B′)₅₊ᵤ₊₂ᵥ(C)₁₂₊₂ₜ₊₃ᵤ₊₃ᵥ:D, wherein 0<t<5, 0<u<15, 0<v<9, A is at least one selected from Y, Ce, Tb, Gd, and Sc, B′ is at least one selected from Al, Ga, TI, In, and B, C is at least one selected from O, S, and Se, and D is at least one selected from Ce and Tb.

19. The light device of claim 12, wherein the light emitting element is a light emitting diode.

20. The light device of claim 19, wherein the wavelength converting substance is formed as an encapsulating material to encapsulate the light emitting diode.

21. The light device of claim 19, further comprising an encapsulating material to encapsulate the light emitting diode and the wavelength converting substance.

22. An encapsulating material for a light emitting diode, comprising:
a matrix; and
at least one wavelength converting substance as claimed in claim 1, dispersed in the matrix.

23. The encapsulating material of claim 22, wherein the wavelength converting material particle comprises fluorescent material, phosphorescent material, dye material, or a combination thereof.

24. The encapsulating material of claim 22, wherein the transparent layer comprises indium tin oxide (ITO) or indium zinc oxide (IZO).

25. The encapsulating material of claim 22, wherein the wavelength converting material particle has a refractive index more than the refractive index of the transparent layer.

26. The encapsulating material of claim 22, wherein the transparent layer has a thickness of 50 Å to 2 μm.

27. The encapsulating material of claim 22, wherein the wavelength converting material particle has a diameter of 5000 Å to 30 μm.

28. The encapsulating material of claim 22, wherein the wavelength converting material particle comprises a material represented by a general formula (A)₃₊ₜ₊ᵤ(B′)₅₊ᵤ₊₂ᵥ(C)₁₂₊₂ₜ₊₃ᵤ₊₃ᵥ:D, wherein 0<t<5, 0<u<15, 0<v<9, A is at least one selected from Y, Ce, Tb, Gd, and Sc, B′ is at least one selected from Al, Ga, TI, In, and B, C is at least one selected from O, S, and Se, and D is at least one selected from Ce and Tb.

29. The encapsulating material of claim 22, wherein the wavelength converting material particle is a material having a function of wavelength conversion and the transparent layer is a layer having a function of scattering.

30. The encapsulating material of claim 22, wherein the matrix comprises epoxy resin.

31. A light device, comprising:
an electron beam emitting element, emitting an electron beam when driven;
a plurality of wavelength converting substances located to receive the electron beam emitted by the electron beam emitting element and converting the electron beam to a light and each wavelength converting substance comprises a wavelength converting material particle and a transparent layer covering the wavelength converting material particle continuously or in an island-like way.
